(19) United States
(12) Patent Application Publication
(10) Pub. No.: US 2026/0282795 A1
(43) Pub. Date: Sep. 17, 2026

(54) SUBSTRATE PROCESSING APPARATUS AND SUBSTRATE PROCESSING METHOD

(71) Applicant: Tokyo Electron Limited, Tokyo (JP)

(72) Inventors: Yuta HAMASHIMA, Kumamoto (JP); Hitoshi KOSUGI, Kumamoto (JP); Itaru KANNO, Kumamoto (JP); Jun NONAKA, Kumamoto (JP)

(21) Appl. No.: 19/168,485

(22) PCT Filed: Mar. 14, 2024
(86) PCT No.: PCT/JP2024/010131

§ 371 Date: Sep. 24, 2025

(30) Foreign Application Priority Data
Mar. 28, 2023 (JP) 2023-051168

(51) Int. Cl. H10P 72/00; H10P 70/00

(52) U.S. Cl. CPC H10P 72/0414; H10P 70/20; H10P 72/0604

(57) ABSTRACT

A substrate processing apparatus includes a cleaner for cleaning a substrate processed in a processor with a cleaning liquid, and a transferrer for transferring the substrate between the processor and the cleaner. The cleaner includes a cleaning tank for storing the cleaning liquid and having a bottomed cylindrical shape with an open top, a switcher including a valve for switching an outflow destination of the cleaning liquid discharged from the cleaning tank between a first pipe connected to a regeneration processor and a second pipe for a waste liquid, a liquid receiver provided to cover at least a peripheral edge portion of an opening of the cleaning tank and to receive droplets of the processing liquid falling from the substrate when the substrate processed in the processor is moved from the processor to the cleaning tank, and a drainage part for discarding the liquid collected by the liquid receiver.

### TECHNICAL FIELD

The present disclosure relates to a substrate processing apparatus and a substrate processing method.

### BACKGROUND

Patent Document 1 discloses a cleaning apparatus that rinses a substrate, which has been processed with a chemical solution, by pure water.

### Prior Art Document

### Patent Document

Patent Document 1: Japanese Laid-Open Publication No. H07-273077

### SUMMARY

The present disclosure provides some embodiments of a substrate processing apparatus and a substrate processing method, which are capable of suppressing a consumption amount of a cleaning liquid for cleaning a substrate.

An example of a substrate processing apparatus includes a processor configured to process a substrate with a processing liquid, a cleaner configured to clean the substrate processed in the processor with a cleaning liquid, and a transferrer configured to transfer the substrate between the processor and the cleaner. The cleaner includes a cleaning tank configured to store the cleaning liquid and having a bottomed cylindrical shape with an open top, a switcher including a valve configured to switch an outflow destination of the cleaning liquid discharged from the cleaning tank between a first pipe connected to a regeneration processor and a second pipe for a waste liquid, a liquid receiver provided to cover at least a peripheral edge portion of an opening of the cleaning tank and configured to receive droplets of the processing liquid falling from the substrate when the substrate processed in the processor is moved from the processor to the cleaning tank, and a drainage part configured to discard the liquid collected by the liquid receiver.

According to the substrate processing apparatus and the substrate processing method of the present disclosure, it is possible to suppress a consumption amount of a cleaning liquid for cleaning a substrate.

### BRIEF DESCRIPTION OF DRAWINGS

FIG. 1 is a top view showing an example of a substrate processing system.

FIG. 2 is a side view showing an example of a cleaning apparatus.

FIG. 3 is a block diagram showing an example of a main part of the substrate processing system.

FIG. 4 is a schematic diagram showing an example of a hardware configuration of a controller.

FIG. 5 is a flowchart for explaining an example of a cleaning process performed in the cleaning apparatus.

FIGS. 6A and 6B are side views showing another example of the cleaning apparatus.

FIG. 7 is a side view showing another example of the cleaning apparatus.

FIG. 8 is a side view showing another example of the cleaning apparatus.

FIGS. 9A and 9B are side views showing another example of the cleaning apparatus.

FIGS. 10A and 10B are side views showing another example of the cleaning apparatus.

FIGS. 11A and 11B are side views showing another example of the cleaning apparatus.

FIGS. 12A and 12B are side views showing another example of the cleaning apparatus.

FIGS. 13A and 13B are side views showing an example of a liquid processing apparatus.

FIG. 14 is a side view showing another example of the liquid processing apparatus.

FIGS. 15A and 15B are side views showing another example of the liquid processing apparatus.

FIGS. 16A to 16C are side views showing another example of the liquid processing apparatus.

### DETAILED DESCRIPTION

In the following description, same elements or elements having the same functions are designated by same reference numerals, and duplicate descriptions thereof will be omitted. In this specification, when referring to up, down, right, and left in the figures, directions of the reference numerals in the figures are used as a reference.

### Configuration of Substrate Processing System

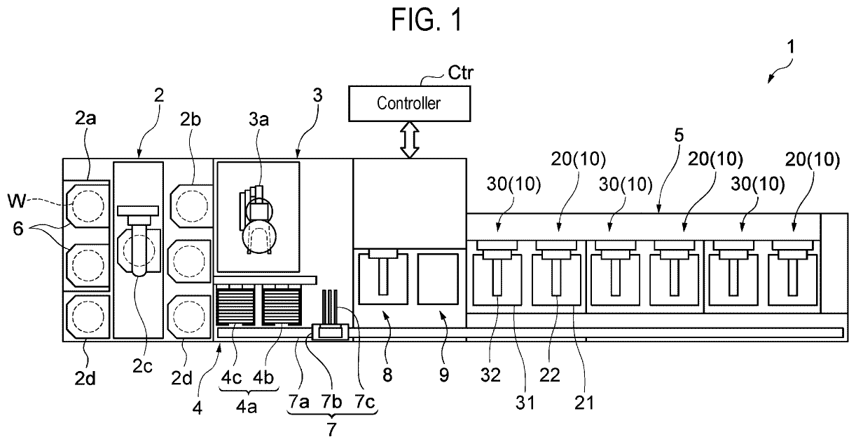

First, a configuration of a substrate processing system 1 (substrate processing apparatus) will be described with reference to FIG. 1. The substrate processing system 1 includes a carrier loader/unloader 2, a lot former 3, a lot placement part 4, a lot processor 5 (substrate processing apparatus), and a controller Ctr (control part).

The carrier loader/unloader 2 includes a stage 2a, a placement table 2b, a transfer mechanism 2c, and a stock 2d. The stage 2a is configured to be capable of placing a plurality of carriers 6 thereon. The placement table 2b is configured to be capable of placing one carrier 6 thereon. The transfer mechanism 2c is located between the stage 2a and the placement table 2b. The transfer mechanism 2c is configured to operate based on an operation signal from the controller Ctr, and to transfer the carrier 6 between the stage 2a, the placement table 2b, and the stock 2d. The stock 2d is configured to temporarily store the carrier 6.

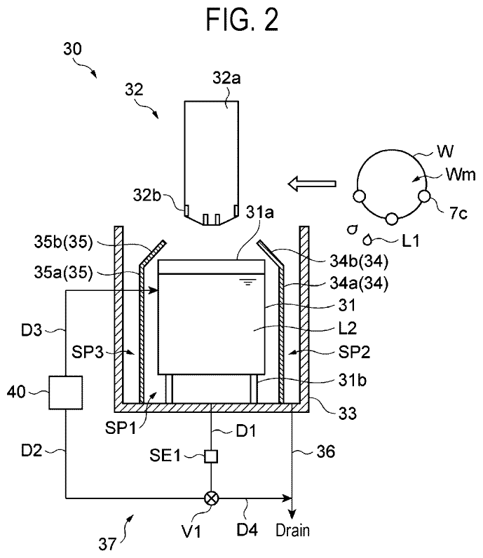

The carrier 6 is configured to be capable of accommodating a plurality of substrates W (for example, 25 substrates) arranged vertically in a horizontal posture. In this specification, the horizontal position refers to a posture in which a main surface Wm (see FIG. 2) of the substrate W extends horizontally. The substrate W may have a disk shape or may have a plate shape other than a circular shape, such as a polygonal shape or the like. The substrate W may have a cutout portion formed by partially cutting the substrate W. The cutout portion may be, for example, a notch (a groove having a U-shape or a V-shape) or a linear portion extending linearly (so-called an orientation flat). The substrate W may be, for example, a semiconductor substrate (silicon wafer), a glass substrate, a mask substrate, an FPD (Flat Panel Display) substrate, or any other type of substrate. A diameter of the substrate W may be, for example, about 200 mm to 450 mm.

The lot former 3 includes a transfer mechanism 3a configured to take out the plurality of substrates W from one or a plurality of carriers 6 to form one lot. The plurality of substrates W (for example, 50 substrates) constituting one lot are simultaneously processed in the lot processor 5. The transfer mechanism 3a operates based on an operation signal from the controller Ctr, and is configured to change the posture of the substrate W between a horizontal posture and a vertical posture during the transfer of the substrate W. In this specification, the vertical posture refers to a posture in which the main surface Wm of the substrate W extends along a vertical direction.

As an example, the transfer mechanism 3a takes out one substrate W from the carrier 6 placed on the placement table 2b, changes a posture of the substrate W to the vertical posture, and transfers the same in the vertical posture to the lot placement part 4. The transfer mechanism 3a repeats this process to form one lot (a plurality of substrates W arranged in the vertical posture one after another) on the lot placement part 4. On the other hand, as an example, the transfer mechanism 3a takes out one substrate W from the lot placed on the lot placement part 4, changes a posture of the substrate W to the horizontal posture, and transfers the same in the horizontal posture to the carrier 6 on the placement table 2b. The transfer mechanism 3a repeats this process to store all of the substrates W that make up the lot in one or more carriers 6.

The lot placement part 4 includes a placement table 4a on which a lot transferred between the lot former 3 and the lot processor 5 is temporarily placed. The placement table 4a may include an unprocessed lot placement table 4b configured to place a lot which has not yet been processed in the lot processor 5, and a processed lot placement table 4c configured to place a lot which has been processed in the lot processor 5.

The lot processor 5 is configured to perform processing such as etching, cleaning, drying, or the like on one lot including the plurality of substrates W arranged one after another in a vertical posture.

### Details of Lot Processor

Hereinafter, the lot processor 5 will be described in detail with reference to FIGS. 1 and 2. The lot processor 5 includes a transfer mechanism 7 (transferror), a drying apparatus 8, a cleaning apparatus 9, and a plurality of liquid processing apparatuses 10.

The transfer mechanism 7 is configured to operate based on an operation signal from the controller Ctr. As illustrated in FIG. 1, the transfer mechanism 7 is configured to transfer a lot between the lot placement part 4, the drying apparatus 8, the cleaning apparatus 9, and the plurality of liquid processing apparatuses 10. The transfer mechanism 7 includes a rail 7a, a moving body 7b, and a holding body 7c (transferror). The rail 7a is arranged so as to extend between the lot placement part 4 and the lot processor 5. The moving body 7b is configured to be movable along the rail 7a. The holding body 7c is provided on the moving body 7b, and configured to hold the lot.

The drying apparatus 8 is configured to operate based on an operation signal from the controller Ctr and to perform a drying process using a drying gas (for example, isopropyl alcohol) on the substrate W. The cleaning apparatus 9 is configured to operate based on an operation signal from the controller Ctr and to perform a cleaning process for the holding body 7c using a cleaning liquid and a drying gas.

The liquid processing apparatus 10 includes a processor 20 and a cleaner 30. The processor 20 is configured to process the substrate W with a processing liquid L1 (see FIG. 2) (for example, perform a process for removing dirt or foreign substance, an etching process, or the like). The cleaner 30 is configured to clean the substrate W processed by the processor 20 with a cleaning liquid L2 (see FIG. 2). A method of cleaning the substrate W in the cleaner 30 may be, for example, overflow rinsing, quick dump rinsing, or the like

The processing liquid L1 may be, for example, an acid-based chemical liquid, an alkaline-based chemical liquid, or an organic chemical liquid. The acid-based chemical liquid may include, for example, a PAN liquid (a mixture of acetic acid, phosphoric acid, nitric acid, and pure water), an SC-2 liquid (a mixture of hydrochloric acid, hydrogen peroxide, and pure water), an SPM (a mixture of sulfuric acid and hydrogen peroxide), an HF liquid (hydrofluoric acid), a DHF liquid (diluted hydrofluoric acid), an HNO₃+HF liquid (a mixture of nitric acid and hydrofluoric acid), and the like. The alkaline-based chemical liquid may include, for example, an SC-1 liquid (a mixture of ammonia, hydrogen peroxide, and pure water), hydrogen peroxide, and the like. The cleaning liquid L2 may include, for example, pure water or ultrapure water (DIW: deionized water), ozone water, functional water (for example, alkaline water, carbonated water (CO₂ water), or the like), ammonia water, and the like.

As illustrated in FIG. 1, the processor 20 includes a processing tank 21 and a holding member 22. The processing tank 21 is configured to store a processing liquid L1.

The holding member 22 is configured to receive one lot from the transfer mechanism 7 and hold the substrates W constituting the lot in a vertical posture. The holding member 22 is connected to a drive mechanism (not shown). The holding member 22 is configured to operate based on an operation signal from the controller Ctr and to move up and down. The holding member 22 may move between, for example, a lowered position where the substrates W held by the holding member 22 are immersed in the processing liquid L1 in the processing tank 21 and a raised position where the substrates W held by the holding member 22 are located above the processing tank 21. At the lowered position, the substrates W held by the holding member 22 are processed by the processing liquid L1 of the processing tank 21. On the other hand, at the raised position, the substrates W held by the holding member 22 are delivered by the transfer mechanism 7.

As illustrated in FIGS. 1 and 2, the cleaner 30 includes a cleaning tank 31, a holding member 32, an accommodation tank 33, liquid receiving members 34 and 35 (liquid receivers), a drain pipe 36 (drainage part), a switcher 37, and a sensor SE1 (measurer).

The cleaning tank 31 is a bottomed cylindrical container having an opening portion 31a (opening) that opens upward. The cleaning tank 31 is configured to store a cleaning liquid L2. The cleaning tank 31 is accommodated inside the accommodation tank 33 via a support member 31b. As illustrated in FIG. 2, the support member 31b may connect the bottom of the cleaning tank 31 to a bottom wall of the accommodation tank 33. Alternatively, the support member 31b may connect the bottom of the cleaning tank 31 to a sidewall of the accommodation tank 33.

The holding member 32 is configured to receive one lot from the transfer mechanism 7 and hold the substrates W constituting the lot in a vertical posture. The holding member 32 is connected to a drive mechanism (not shown). The holding member 32 is configured to operate based on an operation signal from the controller Ctr and to move up and down. The holding member 32 is movable between, for example, a lowered position where the substrates W held by the holding member 32 are immersed in the cleaning liquid L2 in the cleaning tank 31 and a raised position where the substrates W held by the holding member 32 are positioned above the cleaning tank 31. At the lowered position, the substrates W held by the holding member 32 are cleaned by the cleaning liquid L2 in the cleaning tank 31. On the other hand, at the raised position, the substrates W held by the holding member 32 are delivered by the transfer mechanism 7.

The holding member 32 includes a back plate 32a and a plurality of arms 32b. The back plate 32a has a flat plate shape and extends in an up-down direction. The arms 32b are connected to a lower end of the back plate 32a and extend in a direction perpendicular to a main surface of the back plate 32a and in a horizontal direction. The arms 32b are arranged at predetermined intervals in a width direction of the back plate 32a.

An upper surface of the arm 32b is provided with a plurality of grooves (not shown) aligned at approximately equal intervals in an extension direction of the arm 32b. A peripheral edge portion of the substrate W in the vertical posture is arranged in the grooves, so that the substrate W is held by the arm 32b while maintaining the vertical posture. In other words, the arm 32b may support the plurality of substrates W in the vertical posture while being aligned in the extension direction of the arm 32b. The holding member 22 is configured similarly to the holding member 32 described above.

The accommodation tank 33 is a bottomed cylindrical container that opens upward. The accommodation tank 33 is configured to accommodate the cleaning tank 31 therein. The processor 20 may also include a bottomed cylindrical storage tank (collector) configured to accommodate the processing tank 21 therein, just like the accommodation tank 33.

The liquid receiving members 34 and 35 are provided so as to cover at least a peripheral edge portion of the opening portion 31a of the cleaning tank 31. In the example of FIG. 2, the liquid receiving member 34 is located between the right sidewall of the cleaning tank 31 and the right sidewall of the accommodation tank 33. The liquid receiving member 34 extends in an interior of the accommodation tank 33 in a direction perpendicular to the paper in FIG. 2 so as to separate spaces on left and right sides of the liquid receiving member 34. In other words, the liquid receiving member 34 separates a space SP1 on the left side of the liquid receiving member 34, where the cleaning tank 31 is present, from a space SP2 between the liquid receiving member 34 and the right sidewall of the accommodation tank 33.

The liquid receiving member 34 includes a base portion 34a extending upward from the bottom wall of the accommodation tank 33, and an inclined portion 34b extending obliquely from an upper end of the base portion 34a toward the cleaning tank 31. When viewed from above, the inclined portion 34b overlaps a right portion of the peripheral edge portion of the opening portion 31a of the cleaning tank 31. In other words, the liquid receiving member 34 covers the right portion.

In the example of FIG. 2, the liquid receiving member 35 is located between the left sidewall of the cleaning tank 31 and the left sidewall of the accommodation tank 33. The liquid receiving member 35 extends in the interior of the accommodation tank 33 in a direction perpendicular to the paper in FIG. 2 so as to separate spaces on left and right sides of the liquid receiving member 35. In other words, the liquid receiving member 35 separates a space SP1 on the right side of the liquid receiving member 35, where the cleaning tank 31 is present, from a space SP3 between the liquid receiving member 35 and the left sidewall of the accommodation tank 33.

The liquid receiving member 35 includes a base portion 35a extending upward from the bottom wall of the accommodation tank 33, and an inclined portion 35b extending obliquely from an upper end of the base portion 35a toward the cleaning tank 31. When viewed from above, the inclined portion 35b overlaps a left portion of the peripheral edge portion of the opening portion 31a of the cleaning tank 31. In other words, the liquid receiving member 35 covers the left portion.

As shown in FIG. 2, in a case where the substrate W is moved to reach above the cleaning tank 31 from the right side thereof by the holding body 7c and is unloaded from the cleaning tank 31 to the left side after it is subjected to the cleaning process in the cleaning tank 31, the cleaner 30 may include both of the liquid receiving members 34 and 35. On the other hand, in the case where the substrate W is moved to reach above the cleaning tank 31 from the right side thereof by the holding body 7c and is unloaded from the cleaning tank 31 to the right side after it is subjected to the cleaning process in the cleaning tank 31, the cleaner 30 may not include the liquid receiving member 35.

Although not shown, a liquid receiving member configured to cover the entire periphery of the cleaning tank 31 may be employed instead of the liquid receiving members 34 and 35. The liquid receiving member may be configured such that an inner space thereof is separated from a space between an outside thereof and the accommodation tank 33. The liquid receiving member may include a base portion extending upward from the bottom wall of the accommodation tank 33, and an inclined portion extending obliquely from an upper end of the base portion toward the cleaning tank 31. The inclined portion may overlap the entire peripheral edge portion of the opening portion 31a of the cleaning tank 31. In other words, the outer peripheral surface of the inclined portion may have a quadrangular pyramid shape.

The drain pipe 36 extends from the bottom wall of the accommodation tank 33 outward of the accommodation tank 33 so as to communicate with the spaces SP2 and SP3. The drain pipe 36 is configured to discharge the processing liquid L1, which has dropped from the substrate W into the spaces SP2 and SP3 as the substrate W is transferred by the holding body 7c, to the outside as a waste liquid. That is, the processing liquid L1, which has been collected in the spaces SP2 and SP3 defined by the liquid receiving members 34 and 35 and the accommodation tank 33 via the liquid receiving members 34 and 35, is discarded from the drain pipe 36.

The switcher 37 is configured to switch an outflow destination of the cleaning liquid L2 discharged from the cleaning tank 31 to the space SP1 of the accommodation tank 33. The switcher 37 includes pipes D1 to D4 and a valve V1. The pipe D1 extends between the bottom wall of the accommodation tank 33 and the valve V1. The pipe D2 (first pipe) extends between the valve V1 and a regeneration processor 40. The pipe D3 extends between the regeneration processor 40 and the cleaning tank 31. The pipe D4 (second pipe) extends between the valve V1 and the drain pipe 36. The pipe D4 may not be connected to the drain pipe 36, and may extend to the outside of the cleaner 30 separately from the drain pipe 36.

The valve V1 is configured to operate based on an operation signal from the controller Ctr and to switch the outflow destination of the cleaning liquid L2 discharged from the cleaning tank 31 to the accommodation tank 33 between the pipe D2 and the pipe D4. That is, the valve V1 is configured to cause the cleaning liquid L2 flowing from the pipe D1 to flow toward one of the pipes D2 and D4. The valve V1 may be, for example, a three-way valve.

The regeneration processor 40 is configured to regenerate the cleaning liquid L2 flowing through the pipe D2. Specifically, the regeneration processor 40 is configured to perform a process for removing ions contained in the cleaning liquid L2 (ion removal process), and a process for neutralizing an acidic or alkaline component contained in the cleaning liquid L2 (neutralization process) to increase the cleanliness of the cleaning liquid L2. The regeneration processor 40 is configured to return the regenerated cleaning liquid L2 to the cleaning tank 31 via the pipe D4. The regeneration processor 40 may be configured to return the regenerated cleaning liquid L2 to the cleaning tank 31 of another cleaner 30.

The sensor SE1 is configured to measure the cleanliness of the cleaning liquid L2 flowing through the pipe D1 and to transmit the measured value data to the controller Ctr. Here, the “cleanliness” may be one selected from the group consisting of, for example, electrical conductivity, resistivity, and total organic carbon (TOC). Both the electrical conductivity (unit: μS/cm, for example) and the resistivity (unit: MQΩ·cm, for example) are indicators that indicate an amount of an inorganic substance (ion amount) in the cleaning liquid L2. Since the electrical conductivity is defined as the reciprocal of the resistivity, the electrical conductivity and the resistivity may be said to be indicators that indicate essentially the same physical property. The TOC is an indicator that indicates an amount of an organic substance (carbon amount) in the cleaning liquid L2. As the sensor SE1 that measures the TOC over time (in real time), for example, the “TOC sensor 6000TOCi” manufactured by Mettler Toledo Co., Ltd. may be adopted.

### Details of Controller

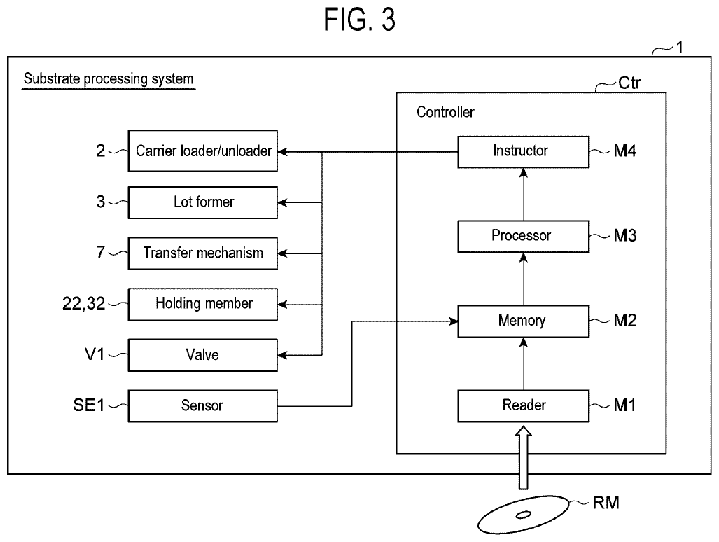

Next, the controller Ctr will be described in more detail with reference to FIG. 3. The controller Ctr includes a reader M1, a memory M2, a processor M3, and an instructor M4 as functional modules. These functional modules are obtained by merely dividing functions of the controller Ctr into multiple modules for the sake of convenience, and do not necessarily mean that the hardware constituting the controller Ctr is divided into such modules. Each functional module is not limited to being implemented by the execution of a program, but may be implemented by a dedicated electric circuit (for example, a logic circuit) or an integrated circuit (ASIC: Application Specific Integrated Circuit) that integrates it.

The reader M1 is configured to read a program from a computer-readable recording medium RM. The recording medium RM records a program for operating each part of the substrate processing system 1. The recording medium RM may be, for example, a semiconductor memory, an optical recording disk, a magnetic recording disk, or a magneto-optical recording disk. In this specification, each part of the substrate processing system 1 may include a carrier loader/unloader 2, a lot former 3, a transfer mechanism 7, holding members 22 and 32, a valve V1, a sensor SE1, and the like.

The memory M2 is configured to store various pieces of data. For example, the memory M2 may store the program read from the recording medium RM by the reader M1, setting parameters (so-called processing recipes) for operating each part of the substrate processing system 1, setting data input by an operator via an external input device (not shown), and the like. The memory M2 may receive data such as the cleanliness of the cleaning liquid L2 measured by the sensor SE1, and may store this data.

The processor M3 is configured to process various pieces of data. The processor M3 may be configured to generate an operation signal for operating each part of the substrate processing system 1 based on, for example, the various pieces of data stored in the memory M2. For example, the processor M3 may compare the data on the cleanliness of the cleaning liquid L2 stored in the memory M2 with a predetermined threshold value Th1 to determine whether or not the cleaning liquid L2 flowing through the pipe D1 is clean enough to be suitable for the regeneration process in the regeneration processor 40. When the processor M3 determines that the cleanliness of the cleaning liquid L2 flowing through the pipe D1 is equal to or higher than the predetermined threshold value Th1, it may generate an operation signal (a control signal for the valve V1) for switching the outflow destination of the cleaning liquid L2 flowing through the pipe D1 to the pipe D2. When the processor M3 determines that the cleanliness of the cleaning liquid L2 flowing through the pipe D1 is less than the predetermined threshold value Th1, it may generate an operation signal (a control signal for the valve V1) for switching the outflow destination of the cleaning liquid L2 flowing through the pipe D1 to the pipe D4.

The instructor M4 is configured to transmit the operation signal generated in the processor M3 to each part of the substrate processing system 1.

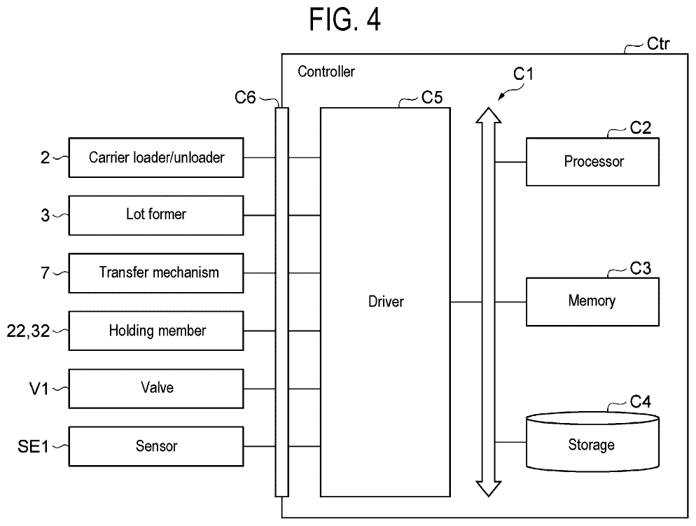

The hardware of the controller Ctr may be formed of, for example, one or more control computers. As shown in FIG. 4, the controller Ctr may include a circuit C1 as a hardware configuration. The circuit C1 may be formed of electric circuit elements (circuitry). The circuit C1 may include, for example, a processor C2, a memory C3, a storage C4, a driver C5, and an input/output port C6.

The processor C2 may be configured to execute a program in cooperation with at least one of the memory C3 or the storage C4 and to input and output signals via the input/output port C6, thereby implementing each of the functional modules described above. The memory C3 and the storage C4 may function as the memory M2. The driver C5 may be a circuit configured to drive each part of the substrate processing system 1. The input/output port C6 may be configured to mediate the input and output of signals between the driver C5 and each part of the substrate processing system 1.

The substrate processing system 1 may include one controller Ctr, or may include a controller group (controller) composed of a plurality of controllers Ctr. When the substrate processing system 1 includes the controller group, the carrier loader/unloader 2, the lot former 3, the lot placement part 4, and the lot processor 5 may be controlled by different controllers Ctr, or at least two of the carrier loader/unloader 2, the lot former 3, the lot placement part 4, and the lot processor 5 may be controlled by one controller Ctr. When the substrate processing system 1 includes the controller group, each of the above-mentioned functional modules may be implemented by one controller Ctr, or may be implemented by a combination of two or more controllers Ctr. When the controller Ctr includes a plurality of computers (circuits C1), each of the above-mentioned functional modules may be implemented by one computer (circuit C1), or may be implemented by a combination of two or more computers (circuits C1). The controller Ctr may include a plurality of processors C2. In this case, each of the above-mentioned functional modules may be implemented by one processor C2, or may be implemented by a combination of two or more processors C2.

### Substrate Processing Method

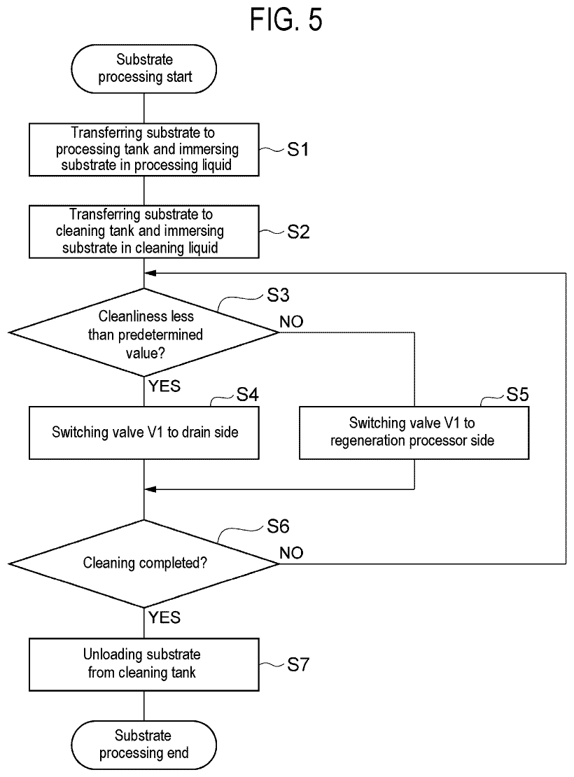

Next, a method of processing the substrate W will be described with reference to FIG. 5. Here, a processing after the lot former 3 takes out the plurality of substrates W from the carrier 6, transfers them to the unprocessed lot placement table 4b, and forms one lot on the unprocessed lot placement table 4b will be described.

First, the controller Ctr instructs the transfer mechanism 7 to have the holding body 7c hold at least one substrate W and transfer the same to the processor 20. Next, the controller Ctr instructs the transfer mechanism 7 to transfer the at least one substrate W from the holding body 7c to the holding member 22 waiting above the processing tank 21. Next, the controller Ctr instructs the holding member 22 to move down into the processing tank 21. As a result, the at least one substrate W held by the holding member 22 is immersed in the processing liquid L1 in the processing tank 21 in a vertical posture (see Step S1 in FIG. 5).

For example, when at least one substrate W is processed in the processing liquid L1 for a predetermined period of time according to a processing recipe, the controller Ctr instructs the holding member 22 to raise the holding member 22 above the processing tank 21. Next, the controller Ctr instructs the holding member 22 to transfer at least one substrate W from the holding member 22 to the holding body 7c of the transfer mechanism 7. Next, the controller Ctr instructs the transfer mechanism 7 to transfer the holding body 7c to the cleaner 30, and then deliver at least one substrate W from the holding body 7c to the holding member 32 waiting above the cleaning tank 31. At this time, since the substrate W is transferred together with the processing liquid L1 adhering thereto, droplets of the processing liquid L1 may fall from the substrate W into the spaces SP2 and SP3. The processing liquid L1 collected in the spaces SP2 and SP3 is discharged to the outside via the drain pipe 36 and then discarded.

Next, the controller Ctr instructs the holding member 32 to move down into the cleaning tank 31. As a result, at least one substrate W held by the holding member 32 is immersed in the cleaning liquid L2 in the cleaning tank 31 in a vertical posture (see Step S2 in FIG. 5). The cleaning liquid L2 discharged from the cleaning tank 31 during the cleaning process for the substrate W in the cleaning tank 31 flows from the space SP1 of the accommodation tank 33 via the pipe D1. At this time, the sensor SE1 measures the cleanliness of the cleaning liquid L2 flowing through the pipe D1 over time (in real time) and transmits the relevant data to the controller Ctr. Based on the data, the controller Ctr determines whether or not the cleanliness measured by the sensor SE1 is less than a predetermined threshold value Th1 (see Step S3 in FIG. 5).

When the result of the determination in Step S3 is that the cleanliness measured by the sensor SE1 is less than the predetermined threshold value Th1 (YES in Step S3 in FIG. 5), the controller Ctr switches the valve V1 so that the outflow destination of the cleaning liquid L2 flowing through the pipe D1 is the pipe D4 (see Step S4 in FIG. 5). In this case, the cleaning liquid L2 is discharged to the outside via the pipe D4 and the drain pipe 36 and discarded.

On the other hand, when the result of the determination in Step S3 is that the cleanliness measured by the sensor SE1 is equal to or greater than the predetermined threshold value Th1 (“NO” in Step S3 in FIG. 5), the controller Ctr switches the valve V1 so that the outflow destination of the cleaning liquid L2 flowing through the pipe D1 is the pipe D2 (see Step S5 in FIG. 5). In this case, the cleaning liquid L2 is regenerated in the regeneration processor 40 and returned to the cleaning tank 31.

In general, immediately after the start of the cleaning process for the substrate W in the cleaning tank 31, the cleanliness measured by the sensor SE1 tends to be low because a relatively large amount of the processing liquid L1 adhering to the substrate W moves to the cleaning tank 31. Thereafter, as the cleaning process for the substrate W in the cleaning tank 31 progresses, the cleanliness measured by the sensor SE1 tends to become higher. Therefore, at the start of the cleaning process, the valve V1 may be switched such that the outflow destination of the cleaning liquid L2 flowing through the pipe D1 is the pipe D4.

In the example of FIG. 2, since the sensor SE1 is arranged upstream of the valve V1, when the sensor SE1 measures a cleanliness that exceeds the predetermined threshold value Th1, the cleaning liquid L2 having a cleanliness equal to or lower than the predetermined threshold value Th1 may be present between the sensor SE1 and the valve V1. Therefore, the controller Ctr may switch the valve V1 when a predetermined period of time (for example, 1 to 5 seconds) has elapsed after the controller Ctr determines that the cleanliness measured by the sensor SE1 is greater than the predetermined threshold value Th1. In this case, the cleaning liquid L2 having a cleanliness that exceeds the predetermined threshold value Th1 may be more reliably supplied to the regeneration processor 40.

After Steps S4 and S5, the controller Ctr determines whether or not the cleaning process for the substrate W in the cleaning tank 31 has been completed (see Step S6 in FIG. 5). The end of the cleaning process may be determined, for example, depending on whether a processing time set in the process recipe has elapsed. Alternatively, the end of the cleaning process may be determined depending on whether or not the cleanliness measured by the sensor SE1 has exceeded a predetermined threshold value Th2. That is, the end of the cleaning process may be determined depending on whether or not the cleaning liquid L2 has become sufficiently clean based on the value measured by the sensor SE1 over time (in real time). In this case, the threshold value Th2 may be set to a value larger than the threshold value Th1.

When the result of the determination in Step S6 is that the cleaning process for the substrate W in the cleaning tank 31 has been completed (“YES” in Step S6 in FIG. 5), the controller Ctr instructs the holding member 32 to move to above the cleaning tank 31. Next, the controller Ctr instructs the holding member 32 to deliver at least one substrate W from the holding member 32 to the holding body 7c of the transfer mechanism 7. Next, the controller Ctr instructs the transfer mechanism 7 to transfer the holding body 7c to the processed lot placement table 4c, and then deliver at least one substrate W from the holding body 7c to the processed lot placement table 4c. In this way, the processing for the substrate W ends.

### Function

According to the above example, the processing liquid L1 that falls from the substrate W is collected in the spaces SP1 and SP2 via the liquid receiving members 34 and 35. Therefore, the amount of processing liquid L1 mixed into the cleaning liquid L2 in the cleaning tank 31 is reduced. Accordingly, the decrease in the cleanliness of the cleaning liquid L2 in the cleaning tank 31 is suppressed, and the amount of cleaning liquid L2 used to remove the processing liquid L1 adhering to the substrate W in the cleaning tank 31 is reduced. In addition, according to the above example, the outflow destination of the cleaning liquid L2 discharged from the cleaning tank 31 is switched between the pipe D2 extending toward the regeneration processor 40 and the pipe D4 for drainage. Therefore, by switching the outflow destination of the cleaning liquid L2 discharged from the cleaning tank 31 depending on the cleanliness of the cleaning liquid L2 discharged from the cleaning tank 31, the regeneration (improvement of cleanliness) of the cleaning liquid L2 by the regeneration processor 40 is promoted. Accordingly, by using the regenerated cleaning liquid L2 in the cleaning tank 31, the addition of a new cleaning liquid L2 is suppressed. As a result, it is possible to reduce the amount of cleaning liquid L2 consumed for cleaning the substrates W.

Incidentally, it is conceivable to fix a timing of the switching operation of the valve V1 according to the processing recipe. In this case, the processing recipe is set with a margin regardless of the number of substrates W to be cleaned in the cleaning tank 31 so that the cleaning liquid L2 having a low cleanliness does not flow into the regeneration processor 40. Therefore, there has been a tendency that regardless of the actual cleaning state of the substrates W, a relatively large amount of the cleaning liquid L2 is used. On the other hand, according to the above example, the controller Ctr controls the switching operation of the valve V1 based on the value measured by the sensor SE1. Therefore, the outflow destination of the cleaning liquid L2 discharged from the cleaning tank 31 is automatically switched between the pipe D2 extending toward the regeneration processor 40 and the pipe D4 for drainage based on the cleanliness of the cleaning liquid L2 measured by the sensor SE1. That is, when the cleaning liquid L2 discharged from the cleaning tank 31 reaches a cleanliness at which the cleaning liquid L2 may be regenerated in the regeneration processor 40, the switching operation of the valve V1 is executed. Therefore, the cleaning liquid L2 that may be regenerated is not discarded but is regenerated without waste and reused as the cleaning liquid L2. Accordingly, it is possible to further reduce the amount of the cleaning liquid L2 consumed for cleaning the substrates W.

### Modification

The disclosure in this specification should be considered as being exemplary and not limitative in all respects. Various omissions, substitutions, modifications, and the like may be made to the above example without departing from the scope and gist of the claims.

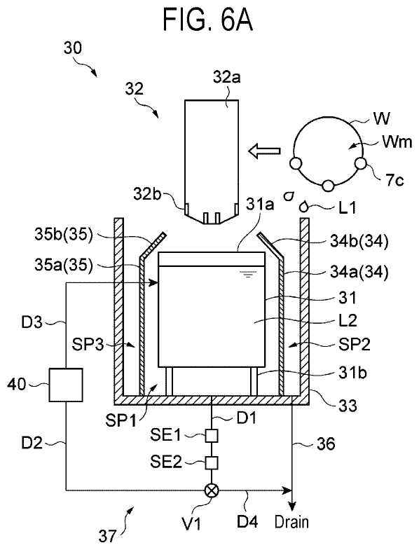

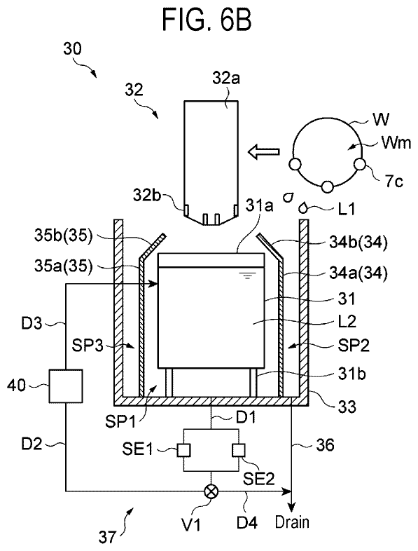

(1) As illustrated in FIGS. 6A and 6B, a plurality of sensors SE1 and SE2 may be used to measure the cleanliness of the cleaning liquid L2 discharged from the cleaning tank 31. That is, the switcher 37 may further include a sensor SE2. In this case, for example, the sensor SE1 may measure electrical conductivity or resistivity, and the sensor SE2 (additional measurer) may measure TOC. Alternatively, the sensor SE1 may measure TOC, and the sensor SE2 may measure electrical conductivity or resistivity.

As illustrated in FIG. 6A, the sensors SE1 and SE2 may be arranged in series with respect to the pipe D1. The arrangement of the sensors SE1 and SE2 (on the upstream or downstream side) is not particularly limited. As illustrated in FIG. 6B, the pipe D1 may branch midway and then merge again, so that the sensors SE1 and SE2 are arranged at the respective branches. That is, the sensors SE1 and SE2 may be arranged in parallel with the pipe D1.

When the substrate W is processed in each of the examples of FIGS. 6A and 6B, it may be determined in Step S3 of FIG. 5 whether or not at least one of a first condition or a second condition is satisfied. The first condition is that the cleanliness measured by the sensor SE1 is less than a predetermined value. The second condition is that the cleanliness measured by the sensor SE2 is less than a predetermined value.

According to the examples of FIGS. 6A and 6B, the amount of an inorganic substance and the amount of an organic substance in the cleaning liquid L2 are measured by two sensors SE1 and SE2, respectively. Therefore, the outflow destination of the cleaning liquid L2 is switched depending on the amount of the inorganic substance and the amount of the organic substance in the cleaning liquid L2. Accordingly, even for the cleaning liquid L2 that may contain both the inorganic substance and the organic substance, the outflow destination of the cleaning liquid L2 is switched depending on the cleanliness of the cleaning liquid L2, so that a larger amount of the cleaning liquid L2 may be regenerated by the regeneration processor 40.

A plurality of sensors SE1 and SE2 may be used in other examples than the examples shown in FIGS. 6A and 6B. In the other examples, the sensors SE1 and SE2 may be arranged in series or in parallel.

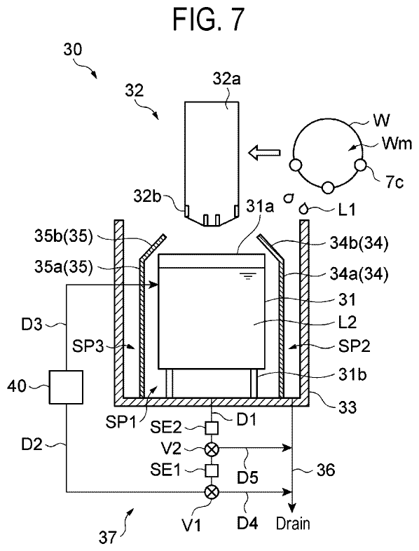

(2) As illustrated in FIG. 7, the switcher 37 may further include a sensor SE2, a pipe D5 (a third pipe), and a valve V2 (another valve). The two sensors SE1 and SE2 may be arranged in series with the pipe D1. The pipe D5 may branch off from the pipe D1 between the sensors SE1 and SE2 and may extend to the drain pipe 36. The sensors SE1 and SE2 may both measure a same index. For example, the sensors SE1 and SE2 may both measure electrical conductivity or resistivity. Alternatively, the sensors SE1 and SE2 may both measure TOC.

The valve V2 may be arranged at a branch point of the pipes D1 and D5. The valve V2 is configured to operate based on an operation signal from the controller Ctr and to switch the outflow destination of the cleaning liquid L2 discharged from the cleaning tank 31 to the accommodation tank 33 between the valve V1 and the pipe D5. That is, the valve V2 is configured to direct the cleaning liquid L2 flowing from the pipe D1 to one of the pipes D1 and D5 extending toward the valve V1. The valve V2 may be, for example, a three-way valve.

In the example of FIG. 7, when the substrate W is processed, the controller Ctr may determine whether or not the cleanliness measured by the sensor SE2 is less than a predetermined threshold value Th3. When the cleanliness measured by the sensor SE2 is less than the predetermined threshold Th3, the controller Ctr may switch the valve V2 so that the outflow destination of the cleaning liquid L2 flowing through the pipe D1 is the pipe D5. In this case, the cleaning liquid L2 is discharged to the outside via the pipe D5 and the drain pipe 36 and discarded. On the other hand, when the cleanliness measured by the sensor SE2 is equal to or greater than the predetermined threshold value Th3, the controller Ctr may switch the valve V2 so that the outflow destination of the cleaning liquid L2 flowing through the pipe D1 is the sensor SE1 and the valve V1.

Thereafter, when the cleaning liquid L2 reaches the sensor SE1 via the valve V2, the controller Ctr may determine whether or not the cleanliness measured by the sensor SE1 is less than the predetermined threshold value Th1, as described in Step S3 of FIG. 5. When the cleanliness measured by the sensor SE1 is less than the predetermined threshold value Th1, the controller Ctr may switch the valve V1 so that the outflow destination of the cleaning liquid L2 flowing through the pipe D1 is the pipe D4. In this case, the cleaning liquid L2 is discharged to the outside via the pipe D4 and the drain pipe 36 and discarded. On the other hand, when the cleanliness measured by the sensor SE1 is equal to or greater than the predetermined threshold value Th1, the controller Ctr may switch the valve V1 so that the outflow destination of the cleaning liquid L2 flowing through the pipe D1 is the pipe D2 and the regeneration processor 40. The threshold values Th1 and Th3 may be the same or different values.

According to the example of FIG. 7, the controller Ctr controls the switching operation of the valves V1 and V2 based on the values measured by the sensors SE1 and SE2. Therefore, for example, by sending the cleaning liquid L2 that exceeds the standard of cleanliness twice to the regeneration processor 40, the mixing of the cleaning liquid L2 having a lower cleanliness into the regeneration processor 40 is suppressed. Accordingly, it is possible to further suppress the consumption amount of the cleaning liquid L2 for cleaning the substrate W. In addition, for example, the controller Ctr determines whether or not a deviation of the values measured by the sensors SE1 and SE2 is within a predetermined range, which makes it possible to detect the failure of the sensor SE1 or the sensor SE2. At this time, a notification sound that notifies that the sensor SE1 or the sensor SE2 may have failed may be generated from a speaker or the like. Alternatively, a notification message that notifies that the sensor SE1 or the sensor SE2 may have failed may be displayed on a display or the like.

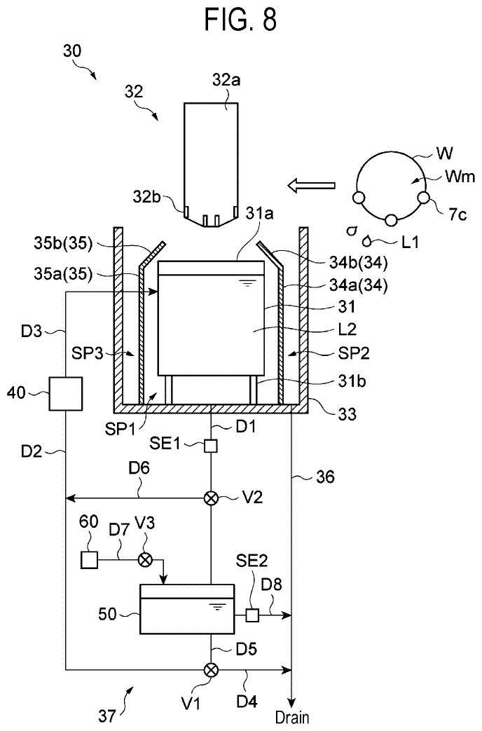

(3) As illustrated in FIG. 8, the cleaning liquid L2 discharged from the cleaning tank 31 may be temporarily stored in a storage tank 50, and pure water or ultrapure water may be supplied to the storage tank 50 to increase the cleanliness of the cleaning liquid L2 in the storage tank 50. For example, the switcher 37 may include pipes D1 to D8, valves V1 to V3, the storage tank 50, and a source 60.

The pipe D1 extends between the bottom wall of the accommodation tank 33 and the storage tank 50. The pipe D2 extends between the valve V1 and the regeneration processor 40. The pipe D3 extends between the regeneration processor 40 and the cleaning tank 31. The pipe D4 extends between the valve V1 and the drain pipe 36. The pipe D5 extends between the bottom wall of the storage tank 50 and the valve V1. The pipe D6 extends between the valve V2 and the pipe D2. The pipe D7 extends between the storage tank 50 and the source 60. The pipe D8 extends between the storage tank 50 and the drain pipe 36. The pipes D4 and D8 are not connected to the drain pipe 36, and may extend to the outside of the cleaner 30 separately from the drain pipe 36.

The valve V1 is configured to operate based on an operation signal from the controller Ctr and to switch the outflow destination of the cleaning liquid L2 discharged from the storage tank 50 between the pipe D2 and the pipe D4. That is, the valve V1 is configured to direct the cleaning liquid L2 flowing from the pipe D5 to one of the pipes D2 and D4. The valve V1 may be, for example, a three-way valve.

The valve V2 is configured to operate based on an operation signal from the controller Ctr and to switch the outflow destination of the cleaning liquid L2 discharged from the cleaning tank 31 to the accommodation tank 33 between the storage tank 50 and the pipe D6. That is, the valve V2 is configured to direct the cleaning liquid L2 flowing from the pipe D1 to one of the storage tank 50 and the pipe D6. The valve V2 may be, for example, a three-way valve.

The valve V3 is configured to be opened and closed based on an operation signal from the controller Ctr. When the valve V3 is opened, the pure water or ultrapure water from the source 60 is supplied to the storage tank 50 via the pipe D7.

The storage tank 50 is configured to temporarily store the cleaning liquid L2 discharged from the cleaning tank 31. A water level gauge (not shown) may be provided in the storage tank 50. A measurement value by the water level gauge may be transmitted to the controller Ctr. The controller Ctr may determine whether or not the cleaning liquid L2 is stored in the storage tank 50 up to an upper capacity limit of the storage tank 50 based on the measurement value obtained by the water level gauge.

The source 60 is configured to store the pure water or ultrapure water to be supplied to the storage tank 50. The pure water or ultrapure water may be supplied from the source 60 to the storage tank 50 continuously or intermittently.

In the example of FIG. 8, the sensor SE1 is configured to measure the cleanliness of the cleaning liquid L2 flowing through the pipe D1 and transmit the measured data to the controller Ctr. The sensor SE2 is configured to measure the cleanliness of the cleaning liquid L2 flowing through the pipe D8 and transmit the measured data to the controller Ctr. Both of the sensors SE1 and SE2 may measure a same or different indexes. For example, both of the sensors SE1 and SE2 may measure conductivity or resistivity. Both of the sensors SE1 and SE2 may measure TOC. Alternatively, one of the sensors SE1 and SE2 may measure conductivity or resistivity, and the other one of the sensors SE1 and SE2 may measure TOC.

In the example of FIG. 8, when the substrate W is processed, when the controller Ctr determines based on the water level gauge (not shown) that the storage tank 50 is not full, the controller Ctr may switch the valve V2 so that the outflow destination of the cleaning liquid L2 flowing through the pipe D1 is the storage tank 50. That is, at the beginning of the cleaning process for the substrate W, the storage tank 50 is empty, and therefore the cleaning liquid L2 having a low cleanliness is stored in the storage tank 50.

On the other hand, when the controller Ctr determines that the storage tank 50 is full based on the water level gauge (not shown), it may determine whether or not the cleanliness measured by the sensor SE1 is less than a predetermined threshold value Th4. When the cleanliness measured by the sensor SE1 is less than the predetermined threshold value Th4, the controller Ctr may switch the valve V2 so that the outflow destination of the cleaning liquid L2 flowing through the pipe D1 is the pipe D6 and the regeneration processor 40. However, when the cleaning process for the substrate W in the cleaning tank 31 has progressed to the extent that the storage tank 50 is full, the cleanliness of the cleaning liquid L2 discharged from the cleaning tank 31 is increased to a certain degree. Therefore, even when the cleanliness measured by the sensor SE1 is less than the predetermined threshold value Th4, the cleaning liquid L2 has a cleanliness suitable for the regeneration process performed in the regeneration processor 40.

On the other hand, when the cleanliness measured by the sensor SE1 is equal to or greater than the predetermined threshold value Th4, the controller Ctr may switch the valve V2 so that the outflow destination of the cleaning liquid L2 flowing through the pipe D1 is the storage tank 50. In this case, the cleaning liquid L2 is temporarily stored in the storage tank 50. That is, the cleaning liquid L2 having a relatively high cleanliness is selectively supplied to the storage tank 50. Therefore, the cleaning liquid L2 in the storage tank 50 is diluted with the cleaning liquid L2 having a relatively high cleanliness. Accordingly, the regeneration of the cleaning liquid L2 in the storage tank 50 is promoted.

The cleaning liquid L2 in the storage tank 50 may be continuously drained from the storage tank 50 via the pipe D8 and the drain pipe 36 and may be discarded. The controller Ctr may determine whether or not the cleanliness measured by the sensor SE2 is less than a predetermined threshold value Th5. When the cleanliness measured by the sensor SE2 is less than the predetermined threshold value Th5, the controller Ctr switches the valve V1 so that the outflow destination of the cleaning liquid L2 flowing from the storage tank 50 via the pipe D5 is the pipe D4. In this case, the cleaning liquid L2 is discharged to the outside via the pipe D4 and the drain pipe 36 and discarded. On the other hand, when the cleanliness measured by the sensor SE2 is equal to or greater than the predetermined threshold value Th5, the controller Ctr may switch the valve V1 so that the outflow destination of the cleaning liquid L2 flowing from the storage tank 50 via the pipe D5 is the pipe D2 and the regeneration processor 40. For example, when the amount of the cleaning liquid L2 stored in the storage tank 50 is less than a predetermined amount, the valve V1 may be switched to close the pipe D5.

According to the example of FIG. 8, even when the cleanliness of the cleaning liquid L2 temporarily stored in the storage tank 50 is low, the cleaning liquid L2 in the storage tank 50 is diluted with the subsequent cleaning liquid L2 from the cleaning tank 31, which has a gradually-increasing cleanliness, and the pure water or ultrapure water from the source 60. This reduces the amount of the cleaning liquid L2 having a low cleanliness to be discarded. Accordingly, it is possible to further suppress the consumption amount of the cleaning liquid L2 for cleaning the substrate W.

When the cleanliness measured by the sensor SE2 is less than a predetermined threshold value Th6, the controller Ctr may control the opening and closing of the valve V3 so that the pure water or ultrapure water is supplied from the source 60 to the storage tank 50. In this case, it is possible to more quickly bring the cleaning liquid L2 in the storage tank 50 to a predetermined cleanliness or higher. In addition, the cleaning liquid L2 having a low cleanliness at the beginning of the cleaning process for the substrate W may be drained via the pipes D5 and D4 and the drain pipe 36.

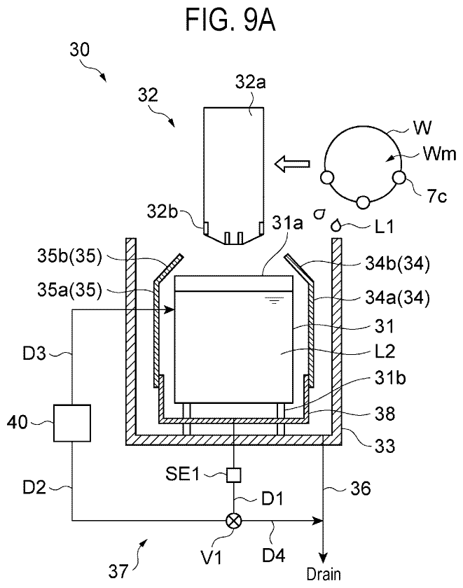

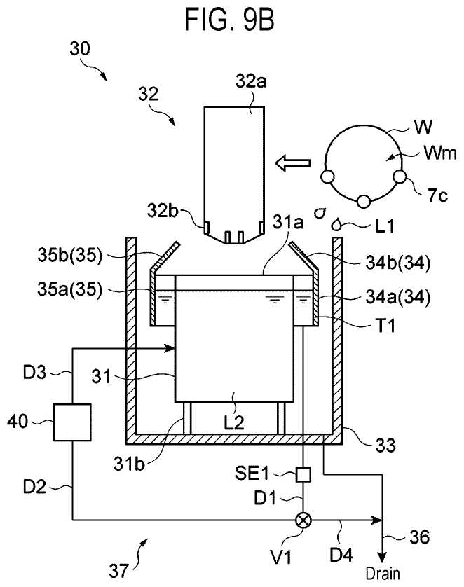

(4) As illustrated in FIG. 9A, an intermediate tank 38 may be provided between the lower portion of the cleaning tank 31 and the accommodation tank 33. The intermediate tank 38 is a bottomed cylindrical container that opens upward. The intermediate tank 38 is configured to cover the lower portion of the cleaning tank 31. In the example of FIG. 9A, the bases 34a and 35a of the liquid receiving members 34 and 35 are connected to an upper portion of the intermediate tank 38 and do not reach the bottom wall of the accommodation tank 33. In addition, the pipe D1 extends between the bottom wall of the intermediate tank 38 and the valve V1. Therefore, the switcher 37 is configured to switch the outflow destination of the cleaning liquid L2 discharged from the cleaning tank 31 to the intermediate tank 38. In the example of FIG. 9A, the same functions and effects as those of the example of FIG. 2 described above may be obtained.

In the example of FIG. 9A, when overflow rinsing is performed as a cleaning method for the substrate W, the cleaning liquid L2 overflowing from the cleaning tank 31 may be collected in the intermediate tank 38 and discharged from the intermediate tank 38 via the pipe D1. In the example of FIG. 9A, when quick dump rinsing is performed as a cleaning method for the substrate W, the cleaning liquid L2 in the cleaning tank 31 may be discharged directly to the pipe D1 via a pipe (not shown) connecting the bottom wall of the cleaning tank 31 and the pipe D1 without passing through the intermediate tank 38.

(5) As illustrated in FIG. 9B, an outer tank T1 (overflow tank) may be provided outside the cleaning tank 31. The outer tank T1 is configured to temporarily store the cleaning liquid L2 that overflows from the cleaning tank 31. In the example of FIG. 9B, the bases 34a and 35a of the liquid receiving members 34 and 35 are connected to an outer peripheral surface of the outer tank T1 and do not reach the bottom wall of the accommodation tank 33. In addition, the pipe D1 extends between a bottom wall of the outer tank T1 and the valve V1. Therefore, the switcher 37 is configured to switch the outflow destination of the cleaning liquid L2 discharged from the cleaning tank 31 to the outer tank T1. The example of FIG. 9B also provides the same functions and effects as those of the example of FIG. 2 described above.

In the example of FIG. 9B, when the overflow rinsing is performed as a cleaning method for the substrate W, the cleaning liquid L2 overflowing from the cleaning tank 31 may be collected in the outer tank T1 and discharged from the outer tank T1 via the pipe D1. In the example of FIG. 9B, when the quick dump rinsing is performed as a cleaning method for the substrate W, the cleaning liquid L2 in the cleaning tank 31 may be collected in the accommodation tank 33 and discharged from the accommodation tank 33 via a pipe (not shown) connecting the bottom wall of the accommodation tank 33 to the pipe D1.

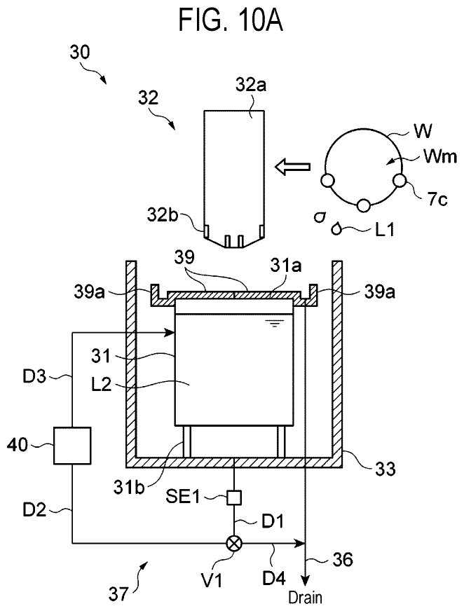

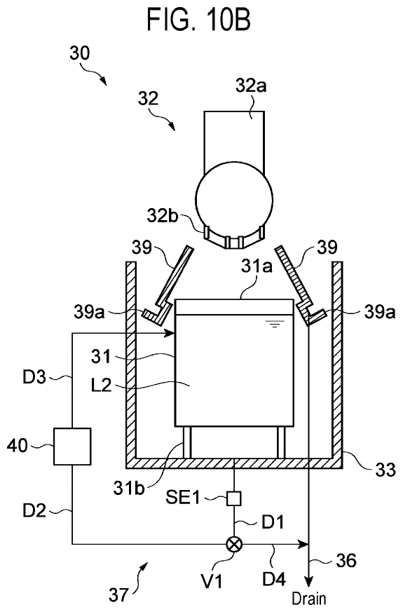

(6) As illustrated in FIGS. 10A and 10B, the cleaner 30 may include a lid member 39 instead of the liquid receiving members 34 and 35 illustrated in FIG. 8. The lid member 39 is configured to operate based on an operation signal from the controller Ctr and to open and close the opening portion 31a of the cleaning tank 31. When the lid member 39 closes the opening portion 31a (see FIG. 10A), the holding member 32 cannot move into the cleaning tank 31, while the processing liquid L1 dropping from the substrate W is prevented from mixing into the cleaning tank 31. Therefore, a decrease in the cleanliness of the cleaning liquid L2 in the cleaning tank 31 is suppressed, and the amount of the cleaning liquid L2 used to remove the processing liquid L1 adhering to the substrate W in the cleaning tank 31 is reduced. Accordingly, it is possible to suppress the consumption amount of the cleaning liquid L2 for cleaning the substrate W. On the other hand, when the lid member 39 opens the opening portion 31a (see FIG. 10B), the holding member 32 may move toward and away from the inside of the cleaning tank 31.

(7) As illustrated in FIGS. 10A and 10B, a gutter member 39a may be provided on the outer peripheral edge of the lid member 39. The gutter member 39a is configured to collect droplets of the processing liquid L1 falling from the substrate W. The gutter member 39a may be, for example, a groove extending along the outer peripheral edge of the lid member 39. In the example of FIGS. 10A and 10B, the drain pipe 36 extends between the bottom wall of the gutter member 39a and the valve V1. Therefore, the processing liquid L1 collected in the gutter member 39a is drained via the drain pipe 36 and discarded. This further prevents the droplets of the processing liquid L1 from being mixed into the cleaning tank 31. As a result, it is possible to suppress the consumption amount of the cleaning liquid L2 for cleaning the substrate W.

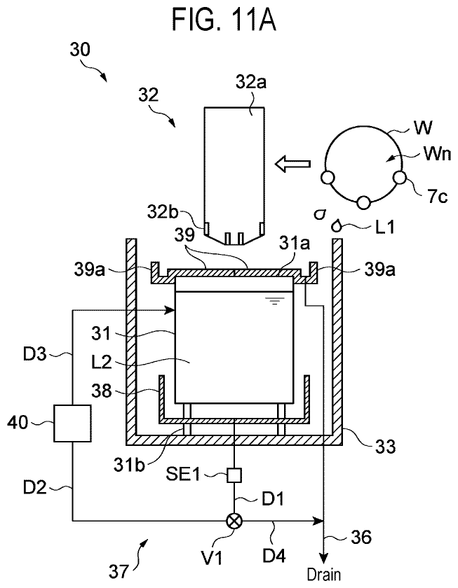

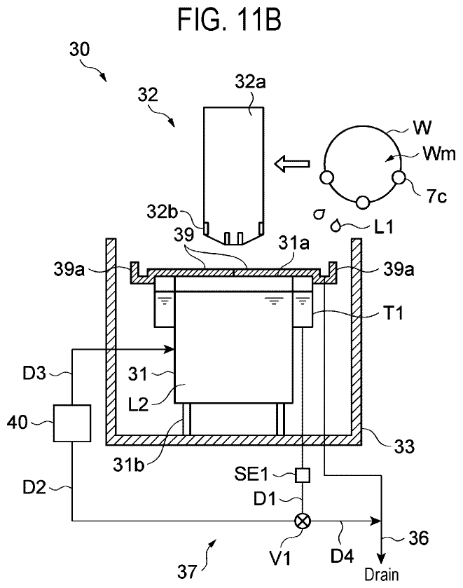

(8) As illustrated in FIG. 11A, the cleaner 30 may include a lid member 39 instead of the liquid receiving members 34 and 35 shown in FIG. 9A. As illustrated in FIG. 11B, the cleaner 30 may include the lid member 39 instead of the liquid receiving members 34 and 35 illustrated in FIG. 9B. In these cases, the same functions and effects as those of the examples of FIGS. 10A and 10B may be obtained.

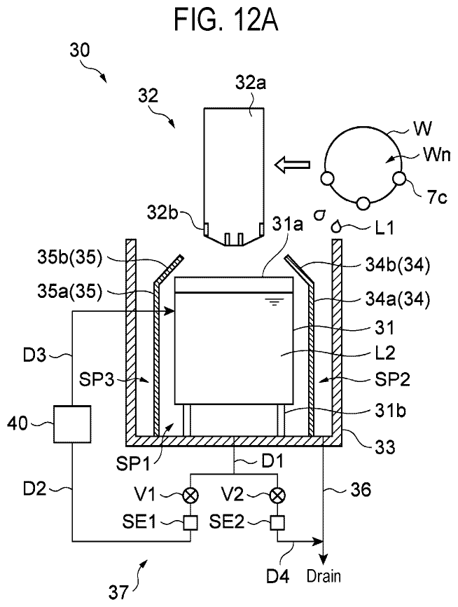

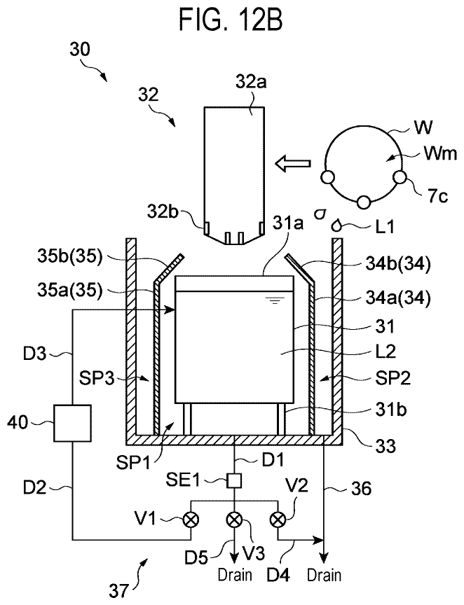

(9) As illustrated in FIG. 12A, the valve V1 and the sensor SE1 may be arranged in the named order in the pipe D2 branched off from the pipe D1. That is, the valve V1 may be arranged upstream of the sensor SE1. Further, the valve V2 and the sensor SE2 may be arranged in the named order in the pipe D4 branched off from the pipe D1. That is, the valve V2 may be arranged upstream of the sensor SE2. In this case, even when values are measured by the sensors SE1 and SE2 with the valves V1 and V2 kept in a closed state, it is possible to detect failures of the valves V1 and V2.

(10) As illustrated in FIG. 12B, three pipes D2, D4, and D5 may branch off from the pipe D1, and valves V1 to V3 may be provided in the pipes D2, D4, and D5, respectively. In this case, for example, the outflow destination of the cleaning liquid L2 may be specified by controlling the opening and closing of the valves V1 to V3 in accordance with the cleanliness of the cleaning liquid L2 measured by the sensor SE1. Therefore, for example, the cleaning liquid L2 may be treated in a treatment facility in accordance with the cleanliness of the cleaning liquid L2.

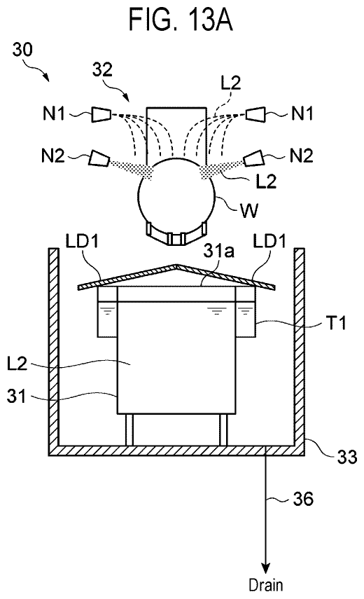

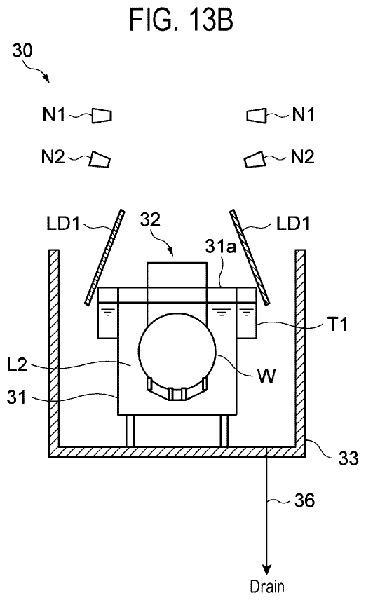

(11) As illustrated in FIGS. 13A and 13B, the cleaner 30 may include a lid member LD1 and sprayers N1 and N2 instead of the liquid receiving members 34 and 35 illustrated in FIG. 2. Although the switcher 37 is not illustrated in FIGS. 13A to 16C, the cleaner 30 may not include the switcher 37 in the examples of FIGS. 13A to 16C. Further, although the cleaner 30 is illustrated in FIGS. 13A to 16C, the processor 20 may include the lid member LD1 and the sprayers N1 and N2. That is, at least one of the processor 20 or the cleaner 30 may include the lid member LD1 and the sprayers N1 and N2.

The cleaner 30 illustrated in FIGS. 13A and 13B may further include an outer tank T1. As in the example of FIG. 9B, the outer tank T1 is configured to temporarily store the cleaning liquid L2 that overflows from the cleaning tank 31 and flows into the outer tank T1.

As in the examples of FIGS. 10A and 10B, the lid member LD1 is configured to operate based on an operation signal from the controller Ctr and to open and close the opening portion 31a of the cleaning tank 31. In the examples of FIGS. 13A and 13B, the lid member LD1 is also configured to be capable of opening and closing the opening portion of the outer tank T1.

The sprayers N1 and N2 are arranged above the cleaning tank 31. As illustrated in FIGS. 13A and 13B, the sprayer N1 may be located above the sprayer N2, or may be located at the same height as the height of the sprayer N2. In the examples of FIGS. 13A and 13B, the cleaner 30 includes two sprayers N1 and N2. However, the cleaner 30 may include at least one sprayer.

The sprayers N1 and N2 are configured to operate based on an operation signal from the controller Ctr and to spray the cleaning liquid L2 onto the substrate W located above the cleaning tank 31. The sprayers N1 and N2 may also spray the cleaning liquid L2 onto a member (for example, the holding member 32 or the holding body 7c) that holds the substrate W. The sprayers N1 and N2 may be configured to spray pure water, ultrapure water, ozone water, or functional water onto the substrate W as the cleaning liquid.

The sprayers N1 and N2 may be configured to spray the cleaning liquid L2 as a shower water flow or a spray flow onto the substrate W. In the examples of FIGS. 13A and 13B, the sprayer N1 sprays the cleaning liquid L2 as a shower water flow onto the substrate W, and the sprayer N2 sprays the cleaning liquid L2 as a spray flow onto the substrate W. However, the present disclosure is not limited thereto. The spray form of the cleaning liquid L2 sprayed by the sprayers N1 and N2 may be reversed. The sprayers N1 and N2 may include a one-fluid nozzle or a two-fluid nozzle.

In the examples of FIGS. 13A and 13B, when the substrate W is processed with the processing liquid L1 in the processor 20, the substrate W is transferred to above the cleaning tank 31. At this time, the lid member LD1 closes the opening portion 31a and the opening portion of the outer tank T1 based on an instruction signal from the controller Ctr. In this state, the controller Ctr instructs the sprayers N1 and N2 to spray the cleaning liquid L2 onto the substrate W located above the cleaning tank 31 (see FIG. 13A). As a result, at least a part of the processing liquid LI adhering to the surface of the substrate W is washed away by the cleaning liquid L2 sprayed onto the substrate W from the sprayers N1 and N2. The processing liquid L1 washed away by the cleaning liquid L2 falls onto the lid member LD1 together with the cleaning liquid L2, and further falls from the lid member LD1 into the accommodation tank 33 (collector). The mixture of the processing liquid L1 and the cleaning liquid L2 collected in the accommodation tank 33 is drained via the drain pipe 36 (additional drainage part) and discarded. Therefore, the washed-away processing liquid L1 is immediately collected, making it possible to restrict the extent to which the processing liquid L1 adheres.

When the cleaning liquid L2 is sprayed from the sprayers N1 and N2 to the substrate W, the nozzles of the sprayers N1 and N2 may move toward and away from the substrate W (may move back and forth). During the spraying, the nozzles of the sprayers N1 and N2 may rotate in the up-down direction. During the spraying, the nozzles of the spraying parts N1 and N2 may rotate in the left-right direction (horizontal direction). During the spraying, the member (for example, the holding member 32 or the holding body 7c) that holds the substrate W may move up and down or may move horizontally.

The spraying of the cleaning liquid L2 from the sprayers N1 and N2 to the substrates W is terminated, for example, when a preset period of processing time has elapsed. When the spraying process of the cleaning liquid L2 is terminated, the controller Ctr instructs the lid member LD1 to move so as to open the opening portion 31a of the cleaning tank 31. Next, the controller Ctr instructs the holding member 32 to move down into the cleaning tank 31 (see FIG. 13B). As a result, at least one substrate W held by the holding member 32 is immersed in the cleaning liquid L2 in the cleaning tank 31 in a vertical posture, and the cleaning process for the substrate W is performed.

According to the examples of FIGS. 13A and 13B, before the substrate W is immersed in the cleaning liquid L2 in the cleaning tank 31, the processing liquid L1 adhering to the substrate W is pre-cleaned by the cleaning liquid L2 sprayed from the sprayers N1 and N2. This reduces the amount of processing liquid L1 mixed into the cleaning liquid L2 in the cleaning tank 31. Accordingly, it is possible to suppress the consumption amount of the cleaning liquid L2 for cleaning the substrate W.

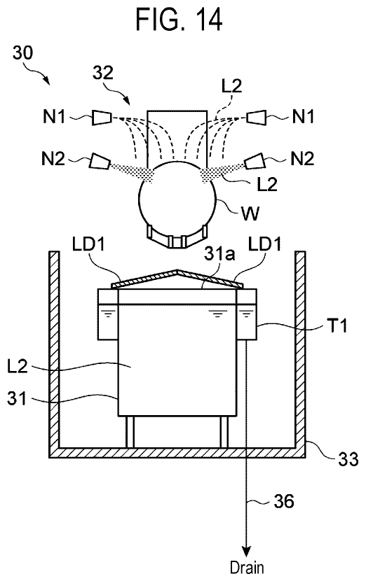

(12) As illustrated in FIG. 14, when the lid member LD1 closes the opening portion 31a of the cleaning tank 31, the lid member LD1 does not have to cover the entire opening portion of the outer tank T1. Further, a drain pipe 36 may be connected to the bottom wall of the outer tank T1. In this case, when the processing liquid L1 falls onto the lid member LD1 together with the cleaning liquid L2, a mixture of the processing liquid L1 and the cleaning liquid L2 flows over the upper surface of the lid member LD1 and into the outer tank T1. The mixture collected in the outer tank T1 is drained through the drain pipe 36 and discarded. In this case, the washed-away processing liquid L1 is immediately collected, making it possible to restrict the extent to which the processing liquid L1 adheres.

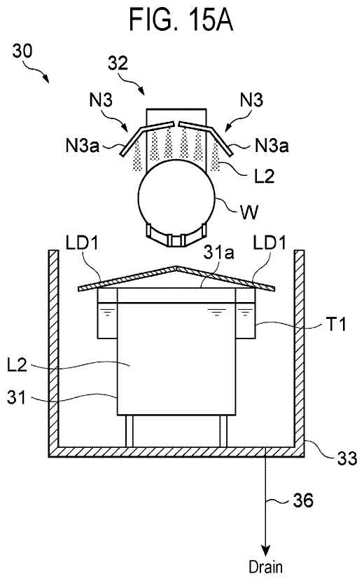

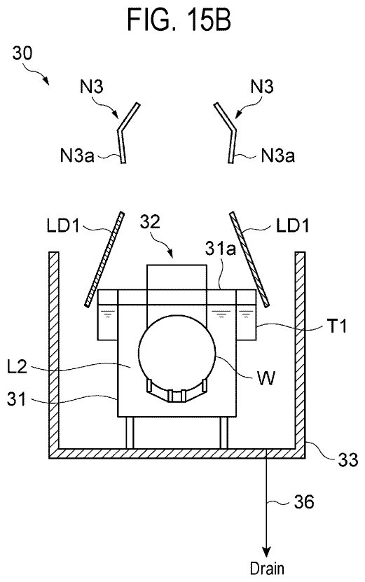

(13) As illustrated in FIGS. 15A and 15B, the cleaner 30 may include a sprayer N3 instead of the sprayers N1 and N2 illustrated in FIGS. 13A and 13B. The sprayer N3 includes a pair of arm members N3a and at least one nozzle (not shown) provided on each arm member N3a.

Each arm member N3a may operate based on an instruction from the controller Ctr. For example, each arm member N3a may be configured to swing between a position where the arm member N3a covers the substrate W from above (see FIG. 15A) when spraying the cleaning liquid L2 onto the substrate W and a position where the arm member N3a retracts when the substrate W moves up and down (see FIG. 15B). As illustrated in FIG. 15A, when each arm member N3a is at the position where the arm member N3a covers the substrate W from above, the lid member LD1 closes the opening portion 31a and the opening portion of the outer tank T1. In this state, the cleaning liquid L2 is sprayed onto the substrate W from the nozzle of each arm member N3a. On the other hand, as illustrated in FIG. 15B, when each arm member N3a is at the retracted position, the respective arm members N3a are separated from each other, and the lid member LD1 opens the opening portion 31a and the opening portion of the outer tank T1. In this state, the holding member 32 is capable of moving up and down between a position within the cleaning tank 31 and a position above the cleaning tank 31.

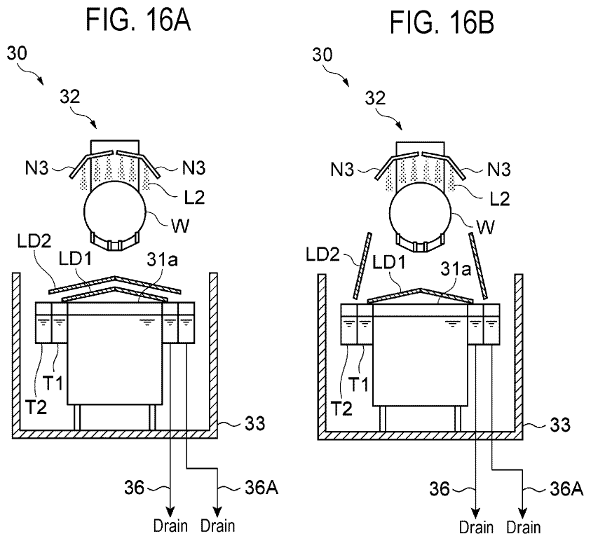

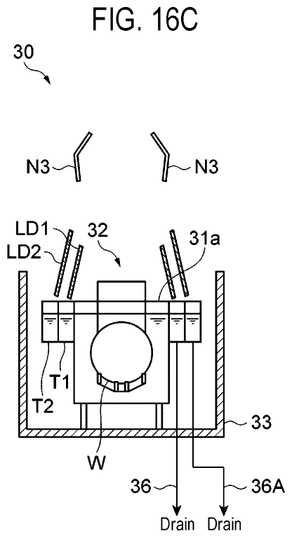

(14) As illustrated in FIGS. 16A to 16C, the cleaner 30 may further include an outer tank T2 (a second outer tank) and a lid member LD2 (additional lid member). In the examples of FIGS. 16A to 16C, the lid member LD1 may not cover the entire opening portion of the outer tank T1, as in the embodiment illustrated in FIG. 14. Although the examples of FIGS. 16A to 16C use the sprayer N3 illustrated in FIGS. 15A and 15B, the sprayers N1 and N2 may be used.

The outer tank T2 is configured to temporarily store the cleaning liquid L2 that overflows from the cleaning tank 31. The outer tank T2 may be arranged on the outer periphery of the outer tank T1. Drain pipes 36 and 36A may be connected to the bottom walls of the outer tanks T1 and T2, respectively.

The lid member LD2 is arranged above the lid member LD1. The lid member LD2 operates based on an operation signal from the controller Ctr and is configured to be capable of opening and closing the opening portion 31a of the cleaning tank 31. As illustrated in FIGS. 16A to 16C, when the lid member LD2 closes the opening portion 31a of the cleaning tank 31, the lid member LD2 does not need to cover the entire opening portion of the outer tank T2.

As illustrated in FIG. 16A, when the cleaning liquid L2 is sprayed from the sprayer N3 onto the substrate W in a state in which both the lid members LD1 and LD2 close the opening portion 31a of the cleaning tank 31, the processing liquid L1 falls onto the lid member LD2 together with the cleaning liquid L2. Therefore, the mixture of the processing liquid L1 and the cleaning liquid L2 flows over the upper surface of the lid member LD2 and into the outer tank T2. The mixture collected in the outer tank T2 is drained through the drain pipe 36A and discarded.

As illustrated in FIG. 16B, when the cleaning liquid L2 is sprayed from the sprayer N3 onto the substrate W in a state in which the lid member LD2 opens the opening portion 31a of the cleaning tank 31 and the lid member LD1 closes the opening portion 31a of the cleaning tank 31, the processing liquid L1 falls onto the lid member LD1 together with the cleaning liquid L2. Therefore, the mixture of the processing liquid L1 and the cleaning liquid L2 flows over the upper surface of the lid member LD1 and into the outer tank T1. The mixture collected in the outer tank T1 is drained through the drain pipe 36 and discarded.

As illustrated in FIG. 16C, when both lid members LD1 and LD2 open the opening portion 31a of the cleaning tank 31, the holding member 32 may move up and down between a position within the cleaning tank 31 and a position above the cleaning tank 31.

According to the examples of FIGS. 16A to 16C, the opening and closing state of the opening portion 31a of the cleaning tank 31 by the lid members LD1 and LD2 is selected according to the type of the processing liquid L1 adhering to the substrate W, and the processing liquid L1 washed off from the substrate W by the cleaning liquid L2 is collected in different outer tanks T1 and T2. Therefore, the mixing of different types of processing liquid L1 is suppressed. Accordingly, it is possible to perform appropriate disposal processing for each processing liquid L1 collected according to its type. In addition, according to the example of FIGS. 16A to 16C, the processing liquid L1 washed off by the cleaning liquid L2 is immediately collected in the outer tanks T1 and T2, making it possible to restrict the extent to which the processing liquid L1 adheres.

### Other Examples

Example 1. An example of a substrate processing apparatus includes a processor configured to process a substrate with a processing liquid, a cleaner configured to clean the substrate processed in the processor with a cleaning liquid, and a transferror configured to transfer the substrate between the processor and the cleaner. The cleaner includes a cleaning tank configured to store the cleaning liquid and having a bottomed cylindrical shape with an open top, a switcher including a valve configured to switch an outflow destination of the cleaning liquid discharged from the cleaning tank between a first pipe connected to a regeneration processor and a second pipe for a waste liquid, a liquid receiver provided to cover at least a peripheral edge portion of an opening of the cleaning tank and configured to receive droplets of the processing liquid falling from the substrate when the substrate processed in the processor is moved from the processor to the cleaning tank, and a drainage part configured to discard the liquid collected by the liquid receiver. Since the processing liquid adheres to the substrate processed with the processing liquid in the processor, the droplets of the processing liquid fall from the substrate when the substrate is transferred from the processor to the cleaner. However, according to the apparatus of Example 1, the cleaner includes the liquid receiver configured to receive the droplets that fall from the substrate. Therefore, the amount of the processing liquid mixed into the cleaning liquid in the cleaning tank is reduced. Accordingly, the decrease in the cleanliness of the cleaning liquid in the cleaning tank is suppressed, so that the amount of the cleaning liquid used to remove the processing liquid adhering to the substrate in the cleaning tank may be reduced. In addition, according to the apparatus of Example 1, the outflow destination of the cleaning liquid discharged from the cleaning tank is switched between the first pipe extending toward the regeneration processor and the second pipe for drainage. Therefore, by switching the outflow destination of the cleaning liquid discharged from the cleaning tank depending on the cleanliness of the cleaning liquid discharged from the cleaning tank, it is possible to promote the regeneration (improvement of cleanliness) of the cleaning liquid by the regeneration processor. Accordingly, by using the regenerated cleaning liquid in the cleaning tank, it is possible to suppress the addition of a new cleaning liquid. As described above, according to the apparatus of Example 1, it is possible to suppress the consumption amount of the cleaning liquid for cleaning the substrate.

Example 2. In the apparatus of Example 1, the cleaner may further include a bottomed cylindrical accommodation tank configured to accommodate the cleaning tank, and the switcher may be configured to switch the outflow destination of the cleaning liquid discharged from the cleaning tank to the accommodation tank. In this case, the same functions and effects as those of Example 1 may be obtained.

Example 3. In the apparatus of Example 1, the cleaner may further include a bottomed cylindrical accommodation tank configured to accommodate the cleaning tank, and a bottomed cylindrical intermediate tank arranged between a lower portion of the cleaning tank and the accommodation tank so as to cover the lower portion of the cleaning tank, and the switcher may be configured to switch the outflow destination of the cleaning liquid discharged from the cleaning tank to the intermediate tank. In this case, the same functions and effects as those of Example 1 may be obtained.

Example 4. In the apparatus of Example 1, the cleaner may further include an outer tank provided outside the cleaning tank and configured to temporarily store the cleaning liquid that overflows from the cleaning tank and flows into the outer tank, and the switcher may be configured to switch the outflow destination of the cleaning liquid discharged from the cleaning tank to the outer tank. In this case, the same functions and effects as those of Example 1 may be obtained.

Example 5. The apparatus of any one of Examples 1 to 4 may further include a controller and a measurer configured to measure a cleanliness of the cleaning liquid discharged from the cleaning tank. The controller may be configured to control a switching operation of the valve based on a value measured by the measurer. Incidentally, it is conceivable that the timing of the switching operation of the valve is fixed by setting parameters (so-called processing recipe) used when operating each part of the substrate processing apparatus. In this case, the processing recipe is set with a margin regardless of the number of substrates to be cleaned in the cleaning tank so that the processing liquid having a low cleanliness does not flow into the regeneration processor. Therefore, regardless of the actual cleaning status of the substrate, there has been a tendency to use a relatively large amount of cleaning liquid. On the other hand, in the case of Example 5, the outflow destination of the cleaning liquid discharged from the cleaning tank is automatically switched between the first pipe extending toward the regeneration processor and the second pipe for drainage based on the cleanliness of the cleaning liquid measured by the measurer. That is, the switching operation of the valve is performed at a timing when the cleaning liquid discharged from the cleaning tank has a cleanliness at which the cleaning liquid may be regenerated in the regeneration processor. Therefore, the recyclable cleaning liquid is not discarded but is regenerated without waste and reused as the cleaning liquid. Accordingly, it is possible to further reduce the consumption amount of the cleaning liquid for cleaning the substrate.

Example 6. In the apparatus of Example 5, the cleanliness of the cleaning liquid measured by the measurer may be one selected from the group consisting of electrical conductivity, resistivity, and TOC. In this case, the amount of an inorganic substance (ion amount) in the cleaning liquid may be checked by measuring the electrical conductivity or the resistivity. In addition, the amount of an organic substance (carbon amount) in the cleaning liquid may be checked by measuring the TOC.

Example 7. The apparatus of Example 5 or 6 may further include an additional measurer configured to measure the cleanliness of the cleaning liquid discharged from the cleaning tank. The measurer and the additional measurer may be arranged in series or parallel to a flow path of the cleaning liquid discharged from the cleaning tank. The cleanliness of the cleaning liquid measured by the measurer may be the electrical conductivity or the resistivity. The cleanliness of the cleaning liquid measured by the additional measurer may be the TOC. The controller may be configured to control the switching operation of the valve based on the values measured by the measurer and the additional measurer. In this case, an amount of the inorganic substance and an amount of the organic substance in the cleaning liquid are measured by the two measurers, respectively. Therefore, the outflow destination of the cleaning liquid is switched depending on the amount of the inorganic substance and the amount of the organic substance in the cleaning liquid. Accordingly, even for a cleaning liquid that may contain both the inorganic substance and the organic substance, the outflow destination of the cleaning liquid is switched depending on the cleanliness of the cleaning liquid, making it possible to regenerate a larger amount of cleaning liquid by the regeneration processor.

Example 8. The apparatus of Example 5 or 6 may further include an additional measurer configured to measure the cleanliness of the cleaning liquid discharged from the cleaning tank. The switcher may further include an additional valve configured to switch the outflow destination of the cleaning liquid discharged from the cleaning tank between the valve and a third pipe for the waste liquid. The valve and the additional valve may be connected in series to a flow path of the cleaning liquid discharged from the cleaning tank. The controller may be configured to control the switching operation of the additional valve based on a value measured by the additional measurer arranged upstream of the additional valve, and to control the switching operation of the valve based on a value measured by the measurer arranged between the valve and the additional valve. In this case, the switching operations of the valve and the additional valve are controlled based on the values measured by the measurer and the additional measurer, respectively. Therefore, for example, by sending a cleaning liquid that exceeds a cleanliness standard twice to the regeneration processor, the mixing of a cleaning liquid having a poor cleanliness into the regeneration processor is suppressed. Therefore, it is possible to further suppress the consumption amount of the cleaning liquid for cleaning the substrate. Further, for example, by having the controller determine whether or not a deviation between the values measured by the measurer and the additional measurer is within a predetermined range, it is possible to detect a failure of the measurer or the additional measurer.

Example 9. In the apparatus of any one of Examples 1 to 8, the liquid receiver may include a lid member configured to be capable of opening and closing the opening of the cleaning tank. In this case, when the lid member closes the opening for the cleaning liquid, the liquid droplets falling from the substrate are prevented from mixing into the cleaning tank. This prevents a reduction of the cleanliness of the cleaning liquid in the cleaning tank, and reduces the amount of the cleaning liquid used to remove the processing liquid adhering to the substrate in the cleaning tank. Accordingly, it is possible to reduce the consumption amount of the cleaning liquid for cleaning the substrate.

Example 10. In the apparatus of Example 9, the liquid receiver may further include a gutter member provided on an outer peripheral edge of the lid member and configured to collect droplets of the processing liquid falling from the substrate. The drainage part may be configured to discard a collected liquid through the gutter member. In this case, the droplets of the processing liquid falling from the substrate are discarded via the gutter member so that the droplets are more effectively prevented from mixing into the cleaning tank. Therefore, it is possible to reduce the consumption amount of the cleaning liquid for cleaning the substrate.

Example 11. The apparatus of Example 9 or 10 may further include a sprayer configured to spray the cleaning liquid onto the substrate located above the lid member in a state in which the opening of the cleaning tank is closed by the lid member. In this case, before the substrate is immersed in the cleaning liquid in the cleaning tank, the cleaning liquid sprayed from the sprayer pre-cleans the processing liquid adhering to the substrate, thereby reducing the amount of the processing liquid mixed into the cleaning liquid in the cleaning tank. Therefore, it is possible to suppress the consumption amount of the cleaning liquid for cleaning the substrate.

Example 12. In the apparatus of Example 11, the sprayer may be configured to spray pure water, ultrapure water, ozone water, or functional water as the cleaning liquid onto the substrate.

Example 13. In the apparatus of Example 11 or 12, the sprayer may be configured to spray the cleaning liquid as a shower water flow or a spray flow onto the substrate located above the lid member.

Example 14. In the apparatus of any one of Examples 11 to 13, the sprayer may include an arm member equipped with a nozzle, and the arm member may be configured to swing between a position where the arm member retracts when the substrate moves up and down and a position where the arm member covers the substrate from above when spraying the cleaning liquid onto the substrate.

Example 15. The apparatus of any one of Examples 9 to 14 may further include a sprayer, wherein the liquid receiver may further include an additional lid member configured to be capable of opening and closing the opening of the cleaning tank, the cleaner may further include first and second outer tanks provided outside the cleaning tank and configured to temporarily store the cleaning liquid that overflows from the cleaning tank and flows into the outer tanks, the sprayer may be configured to spray the cleaning liquid onto the substrate located above the lid member or the additional lid member in a state in which the opening of the cleaning tank is closed by the lid member or the additional lid member, the first outer tank may be configured to collect the cleaning liquid sprayed onto the substrate by the sprayer in a state in which the lid member closes the opening of the cleaning tank, and the second outer tank may be configured to collect the cleaning liquid sprayed onto the substrate by the sprayer in a state in which the additional lid member closes the opening of the cleaning tank. In this case, the processing liquid washed off from the substrate by the cleaning liquid is collected in different outer tanks by selecting the open/closed state of the opening of the cleaning tank by the lid member and the additional lid member according to the type of processing liquid adhering to the substrate. Therefore, the mixing of different types of processing liquid is suppressed. Accordingly, it is possible to carry out appropriate disposal processing for each type of collected processing liquid.

Example 16. The apparatus of any one of Examples 1 to 15 may further include a sprayer, wherein the processor may further include a processing tank configured to store the processing liquid and having a bottomed cylindrical shape with an open top, and a lid member configured to be capable of opening and closing the opening of the processing tank. The sprayer may be configured to spray the cleaning liquid onto the substrate located above the lid member in a state in which the opening of the processing tank is closed by the lid member. In this case, the same functions and effects as those of the apparatus of Example 11 may be obtained.

Example 17. In the apparatus of Example 16, the processor may further include a collector configured to collect the cleaning liquid sprayed onto the substrate by the sprayer in a state in which the lid member closes the opening of the processing tank, and an additional drainage part configured to discard the processing liquid collected by the collector. In this case, the processing liquid washed off from the substrate by the pre-cleaning is discarded via the collector. Therefore, since the washed-off processing liquid is immediately collected, it is possible to restrict the extent to which the processing liquid adheres.

Example 18. In the apparatus of Example 16 or 17, the sprayer may be configured to spray the cleaning liquid as a shower water flow or a spray flow onto the substrate located above the lid member.

Example 19. In the apparatus of any one of Examples 16 to 18, the sprayer may include an arm member equipped with a nozzle. The arm member may be configured to swing between a position where the arm member retracts when the substrate moves up and down and a position where the arm member covers the substrate from above when spraying the cleaning liquid onto the substrate.

Example 20. An example of a substrate processing method includes processing a substrate with a processing liquid in a processor, transferring the substrate from the processor to a cleaner, and cleaning the substrate processed in the processor with a cleaning liquid in the cleaner. The cleaner includes a cleaning tank configured to store the cleaning liquid and having a bottomed cylindrical shape with an open top, a switcher including a valve configured to switch an outflow destination of the cleaning liquid discharged from the cleaning tank between a first pipe connected to a regeneration processor and a second pipe for a waste liquid, a liquid receiver provided to cover at least a peripheral edge portion of an opening of the cleaning tank and configured to receive droplets of the processing liquid falling from the substrate when the substrate processed in the processor is moved from the processor to the cleaning tank, and a drainage part configured to discard the liquid collected by the liquid receiver. In this case, the same functions and effects as those of the apparatus of Example 1 may be obtained.

### Explanation of Reference Numerals

1: substrate processing system (substrate processing apparatus), 5: lot processor (substrate processing apparatus), 7: transfer mechanism (transferror), 10: liquid processing apparatus, 20: processor, 21: processing tank, 30: cleaner, 31: cleaning tank, 31a: opening portion (opening), 33: accommodation tank (collector), 34, 35: liquid receiving member (liquid receiver), 36: drain pipe (drainage part and additional drainage part), 37: switcher, 38: tank, 40: regeneration processor, Ctr: controller (controller), D2: pipe (first pipe), D4: pipe (second pipe), D5:. pipe (third pipe), L1: processing liquid, L2: cleaning liquid, LD1: lid member, LD2: lid member (additional lid member), N1 to N3: sprayer, N3a: arm member, SE1: sensor (measurer), SE2: sensor (additional measurer), T1: outer tank (first outer tank), T2: outer tank (second outer tank), V1: valve, V2: valve (additional valve), W: substrate

1. A substrate processing apparatus, comprising:
a processor configured to process a substrate with a processing liquid;
a cleaner configured to clean the substrate processed in the processor with a cleaning liquid; and
a transferrer configured to transfer the substrate between the processor and the cleaner,
wherein the cleaner includes:
a cleaning tank configured to store the cleaning liquid and having a bottomed cylindrical shape with an open top;
a switcher including a valve configured to switch an outflow destination of the cleaning liquid discharged from the cleaning tank between a first pipe connected to a regeneration processor and a second pipe for a waste liquid;
a liquid receiver provided to cover at least a peripheral edge portion of an opening of the cleaning tank and configured to receive droplets of the processing liquid falling from the substrate when the substrate processed in the processor is moved from the processor to the cleaning tank; and
a drainage part configured to discard the liquid collected by the liquid receiver.

2. The substrate processing apparatus of claim 1, wherein the cleaner further includes a bottomed cylindrical accommodation tank configured to accommodate the cleaning tank, and
wherein the switcher is configured to switch the outflow destination of the cleaning liquid discharged from the cleaning tank to the accommodation tank.

3. The substrate processing apparatus of claim 1, wherein the cleaner further includes a bottomed cylindrical accommodation tank configured to accommodate the cleaning tank, and a bottomed cylindrical intermediate tank arranged between a lower portion of the cleaning tank and the accommodation tank so as to cover the lower portion of the cleaning tank, and
wherein the switcher is configured to switch the outflow destination of the cleaning liquid discharged from the cleaning tank to the intermediate tank.

4. The substrate processing apparatus of claim 1, wherein the cleaner further includes an outer tank provided outside the cleaning tank and configured to temporarily store the cleaning liquid that overflows from the cleaning tank and flows into the outer tank, and
wherein the switcher is configured to switch the outflow destination of the cleaning liquid discharged from the cleaning tank to the outer tank.

5. The substrate processing apparatus of claim 1, further comprising:
a controller; and
a measurer configured to measure a cleanliness of the cleaning liquid discharged from the cleaning tank,
wherein the controller is configured to control a switching operation of the valve based on a value measured by the measurer.

6. The substrate processing apparatus of claim 5, wherein the cleanliness of the cleaning liquid measured by the measurer is one selected from a group consisting of electrical conductivity, resistivity, and TOC.

7. The substrate processing apparatus of claim 5, further comprising:
an additional measurer configured to measure the cleanliness of the cleaning liquid discharged from the cleaning tank,
wherein the measurer and the additional measurer are arranged in series or parallel to a flow path of the cleaning liquid discharged from the cleaning tank,
wherein the cleanliness of the cleaning liquid measured by the measurer is electrical conductivity or resistivity,
wherein the cleanliness of the cleaning liquid measured by the additional measurer is TOC, and
wherein the controller is configured to control the switching operation of the valve based on the values measured by the measurer and the additional measurer.

8. The substrate processing apparatus of claim 5, further comprising:
an additional measurer configured to measure the cleanliness of the cleaning liquid discharged from the cleaning tank,
wherein the switcher further includes an additional valve configured to switch the outflow destination of the cleaning liquid discharged from the cleaning tank between the valve and a third pipe for the waste liquid,
wherein the valve and the additional valve are connected in series to a flow path of the cleaning liquid discharged from the cleaning tank, and
wherein the controller is configured to control a switching operation of the additional valve based on a value measured by the additional measurer arranged upstream of the additional valve, and to control the switching operation of the valve based on a value measured by the measurer arranged between the valve and the additional valve.

9. The substrate processing apparatus of claim 1, wherein the liquid receiver includes a lid member configured to be capable of opening and closing the opening of the cleaning tank.

10. The substrate processing apparatus of claim 9, wherein the liquid receiver further includes a gutter member provided on an outer peripheral edge of the lid member and configured to collect droplets of the processing liquid falling from the substrate, and
wherein the drainage part is configured to discard the processing liquid collected by the gutter member.

11. The substrate processing apparatus of claim 9, further comprising:
a sprayer configured to spray the cleaning liquid onto the substrate located above the lid member in a state in which the opening of the cleaning tank is closed by the lid member.

12. The substrate processing apparatus of claim 11, wherein the sprayer is configured to spray pure water, ultrapure water, ozone water, or functional water as the cleaning liquid onto the substrate.

13. The substrate processing apparatus of claim 11, wherein the sprayer is configured to spray the cleaning liquid as a shower water flow or a spray flow onto the substrate located above the lid member.

14. The substrate processing apparatus of claim 11, wherein the sprayer includes an arm member equipped with a nozzle, and
wherein the arm member is configured to swing between a position where the arm member retracts when the substrate moves up and down and a position where the arm member covers the substrate from above when spraying the cleaning liquid onto the substrate.

15. The substrate processing apparatus of claim 9, further comprising:
a sprayer,
wherein the liquid receiver further includes an additional lid member configured to be capable of opening and closing the opening of the cleaning tank,
wherein the cleaner further includes a first outer tank and a second outer tank provided outside the cleaning tank and configured to temporarily store the cleaning liquid that overflows from the cleaning tank and flows into the first outer tank and the second outer tank,
wherein the sprayer is configured to spray the cleaning liquid onto the substrate located above the lid member or the additional lid member in a state in which the opening of the cleaning tank is closed by the lid member or the additional lid member,
wherein the first outer tank is configured to collect the cleaning liquid sprayed onto the substrate by the sprayer in a state in which the lid member closes the opening of the cleaning tank, and
wherein the second outer tank is configured to collect the cleaning liquid sprayed onto the substrate by the sprayer in a state in which the additional lid member closes the opening of the cleaning tank.

16. The substrate processing apparatus of claim 1, further comprising:
a sprayer,
wherein the processor further includes a processing tank configured to store the processing liquid and having a bottomed cylindrical shape with an open top, and a lid member configured to be capable of opening and closing the opening of the processing tank, and
wherein the sprayer is configured to spray the cleaning liquid onto the substrate located above the lid member in a state in which the opening of the processing tank is closed by the lid member.

17. The substrate processing apparatus of claim 16, wherein the processor further includes a collector configured to collect the cleaning liquid sprayed onto the substrate by the sprayer in a state in which the lid member closes the opening of the processing tank, and an additional drainage part configured to discard the processing liquid collected by the collector.

18. The substrate processing apparatus of claim 16, wherein the sprayer is configured to spray the cleaning liquid as a shower water flow or a spray flow onto the substrate located above the lid member.

19. The substrate processing apparatus of claim 16, wherein the sprayer includes an arm member equipped with a nozzle, and
wherein the arm member is configured to swing between a position where the arm member retracts when the substrate moves up and down and a position where the arm member covers the substrate from above when spraying the cleaning liquid onto the substrate.

20. A substrate processing method, comprising:
processing a substrate with a processing liquid in a processor;
transferring the substrate from the processor to a cleaner; and
cleaning the substrate processed in the processor with a cleaning liquid in the cleaner,
wherein the cleaner includes:
a cleaning tank configured to store the cleaning liquid and having a bottomed cylindrical shape with an open top;
a switcher including a valve configured to switch an outflow destination of the cleaning liquid discharged from the cleaning tank between a first pipe connected to a regeneration processor and a second pipe for a waste liquid;
a liquid receiver provided to cover at least a peripheral edge portion of an opening of the cleaning tank and configured to receive droplets of the processing liquid falling from the substrate when the substrate processed in the processor is moved from the processor to the cleaning tank; and
a drainage part configured to discard the liquid collected by the liquid receiver.
